(19) United States
(12) Patent Application Publication
(10) Pub. No.: US 2026/0363079 A1
(43) Pub. Date: Nov. 12, 2026

(54) PROCESSES AND APPARATUSES FOR ADJUSTING A TEMPERATURE OF AN ELECTRONIC DEVICE

(71) Applicant: Solstice Advanced Materials US, Inc., Morris Plains, NJ (US)

(72) Inventors: Arad Azizi, Buffalo, NY (US); Robert J. Stewart, East Aurora, NJ (US); Nitin Karwa, Getzville, NY (US); Arielle Marie Rivera Gamboa, Buffalo, NY (US)

(21) Appl. No.: 19/665,617

(22) Filed: May 1, 2026

Related U.S. Application Data
(60) Provisional application No. 63/800,911, filed on May 6, 2025.

(51) Int. Cl. H10W 40/73; H10W 40/20; H10W 40/47

(52) U.S. Cl. CPC H10W 40/73; H10W 40/242; H10W 40/475

(57) ABSTRACT

Processes and apparatuses for controlling a temperature of an electronic device such as a processor by directing cooling fluid to different sections of a processor depending on the temperature and/or power consumption of that section. Channels are provided in the device or in a cold plate that allow for a flow rate of a cooling fluid within the channels to be adjusted independently of other channels.

### RELATED APPLICATIONS

This application claims priority to U.S. Provisional Patent Application No. 63/800,911, filed on May 6, 2025, the entirety of which is incorporated herein by reference.

### FIELD OF THE INVENTION

This invention relates generally to processes and apparatuses for adjusting a temperature of an electronic device, such as addressing a heat flux of a processor, and more specifically, to processes and apparatuses that direct cooling fluid to different sections of an electronic device, such as a processor, depending on the temperature and/or heat flux of the section.

### BACKGROUND OF THE INVENTION

Thermal management of high heat flux chips for artificial intelligence (AI) and high-performance computing (HPC) has become a bottleneck in compute performance due to total device power (TDP) of chips used in such applications as central processing units (CPUs) and graphical processing units (GPUs). The junction (transistor) temperature in such chips generally needs to operate under 80 °C for reliability and longer mean-time-to-failure. On the other hand, there is a growing push for high facility water supply temperatures (FWS) as high as 60 °C for primary heat rejection cycle in data centers to provide significant water and energy savings.

Two-phase configurations for data center thermal management including two-phase direct-to-chip address this bottleneck by using latent heat of vaporization in flow boiling regimes. Additionally, FWS requirements for sustainable operation can be achieved by using two-phase configurations by adiabatic cooling.

One of the key parameters in the performance of two-phase systems is junction-to-liquid thermal resistance in the secondary heat rejection loop. The lower the thermal resistance, the chip can output more computation with higher power (TDP) while maintaining safe and reliable junction temperatures.

The secondary heat rejection loop for a two-phase direct-to-chip system includes a cooling distribution unit (CDU), piping, rack manifolds, control valves, and cold plates.

One of the key challenges in two-phase direct-to-chip systems is flow control. In two phase direct-to-chip cold plates, the refrigerant enters from one side and as the liquid flows on the high heat flux surface, the refrigerant reaches saturation temperature and boils. Vapor quality in such systems has direct effect on the performance of cooling and flow boiling heat transfer coefficient. If the liquid is subcooled, the liquid may not boil in the entrance region of the cold plate and single-phase convective cooling occurs. If the refrigerant enters the cold plate at near saturation conditions, the refrigerant starts boiling immediately. Depending on the heat flux, high vapor qualities and even dry-out conditions may occur in the cold plate.

The chip heat flux (background heat flux and hot spots) changes over time based on computational load and chip utilization. As a result of the transient heat flux, the boiling surface experiences a time-varying process which affects junction temperature across the silicon die and on each core or processing unit. Consequently, designing a cold plate with a fixed design or a certain degree of subcooling is not efficient.

Currently, systems' attempt to solve this issue in two-phase direct-to-chip systems is to use flow control valves to increase or decrease the flow rate of refrigerant entering the cold plate. However, such control is not precision control and cannot provide a precise temperature control on the cold plate and has delay.

There is thus an ongoing need for more effective and efficient ways to utilize a cooling system in an electronic device.

### SUMMARY OF THE INVENTION

The present inventors have discovered devices and processes which offer a dynamic cold plate design that provides precision flow control on an electronic device, like a chip based on computational load and transient heat fluxes. The present disclosure is preferably utilized on a processor; however, it is contemplated that other electronic devices may be utilized in conjunction with the present invention. Thus, the remaining disclosure with respect to sections of a processor or chip is merely preferred and not intended to be limiting.

The cold plate for single phase and two-phase direct-to-chip is similar to current microchannel geometry or other geometries; however, micro-actuators similar to micro-electromechanical system (MEMS) devices may be installed on the channels to change the width of the channel or distance between fins or other heat transfer structures to control the local flow rate and associated pressure drops. Such flow control can also be implemented on a manifold instead of the cold plate. Additionally, in systems with embedded cooling where microchannels are directly etched on the silicon device, MEMS actuators can be implemented for flow control. It is also possible to provide such active control on the back of the internal heat spreader (IHS) for cooling devices that require elimination of thermal interface material 2 (TIM2) and have manifolds directly on the back of the IHS.

In single-phase direct-to-chip cooling, coolant may be water or a water-glycol mixture, including PG25 which is a mixture of water and propylene glycol in a 3:1 volume ratio. Ethylene glycol may also be used as the glycol component. In this cooling configuration, heat is removed by coolant due to sensible heating and convection: as the chip power increases, the heat produced at the die is transferred to the flow of coolant which then heats up. To meet the more aggressive cooling requirements of higher power chips, coolant flow rate can be increased and/or inlet temperature can be decreased. In the laminar flow regime, heat transfer coefficient increases with an increase in flow rate. Because cold plates typically use small channels that are classified as microchannels, the flow typically remains in the laminar regime. This means that increasing the supply of cool fluid improves cooling performance. In flow-optimized single-phase cold plates, engineers design for the worst-case scenario of chip thermal maps. However, as chip powers continue to increase, this approach may not be feasible due to the higher flow rates required and forced through small channels. Excessively high flow rates can lead to extra pressure drops as well as erosion/corrosion of the cold plate. Therefore, a method for dynamically adjusting cooling channels will be beneficial in handling transient loads and migrating hotspots in single-phase cooling. This targeted cooling scheme can provide a method to efficiently cool the chip while allowing for transient heat fluxes across a single chip or multi-chip package/module.

The actuators move physical components on the cold plate and/or actively or passively change the geometry such as channel width and optimize the flow rate based on the heat flux, junction temperature, silicon temperature, cold plate temperature, and inlet/outlet pressure of the cold plate. The control of the actuators is preferably based on temperatures of different locations on the chip. For example, as core 2 of a 128 core CPU has a higher temperature, a channel width on top of the core may expand to facilitate higher local flow rate and better or increased cooling. On the other hand, if cores of a certain region of the chip are not being utilized and the background heat flux is low, the associated channels may become narrower to reduce flow rate and still achieve efficient boiling and avoid single-phase heat transfer.

Therefore, the present invention may be characterized, in at least one aspect, as providing a device with a source of a cooling fluid; a first cooling channel in fluid communication with the source of the cooling fluid and configured to receive a first portion of the cooling fluid which receives heat transferred from a first section of an electronic component having a first functionality; and, a second cooling channel in fluid communication with the source of the cooling fluid and configured to receive a second portion of the cooling fluid which receives heat transferred from a second section of the electronic component having a second functionality, the second functionality being the same as or different from the first functionality. A flow rate of the first portion of the cooling fluid in the first cooling channel may be configured to be controlled independently from a flow rate of the second portion of the cooling fluid in the second cooling channel.

The present invention may also be generally characterized, in at least one aspect, as providing a device including: a source of a cooling fluid; a first plurality of cooling channels in fluid communication with the source of the cooling fluid and configured to receive a first portion of the cooling fluid which receives heat transferred from a first section of a chip having a first functionality; and, a second plurality of cooling channels in fluid communication with the source of the cooling fluid and configured to receive a second portion of the cooling fluid which receives heat transferred from a second section of the chip having a second functionality, the second functionality being the same as or different from the first functionality. A flow rate of the first portion of the cooling fluid in the first plurality of cooling channels may be controlled independently from a flow rate of the second portion of the cooling fluid in the second plurality of cooling channels. The cooling fluid may be a two-phase cooling fluid or a single phase cooling fluid.

The first plurality of cooling channels may be formed integrally with the first section of the chip, or the second plurality of cooling channels may be formed integrally with the second section of the chip, or both.

A flow rate through each channel may be individually controlled.

A flow rate though at least two channels from the first plurality of cooling channels may be controlled together, or a flow rate though at least two channels from the second plurality of cooling channels may be controlled together, or both.

The first plurality of cooling channels may receive the first portion of the cooling fluid which further receives heat transferred from a first section of a second chip. The second chip may be different from the chip.

The first plurality of cooling channels may be jet impingement channels, or wherein the second plurality of cooling channels may be jet impingement channels, or both.

A porous member may be provided between the channels and the chip.

The first plurality of cooling channels may be formed integrally with a first cold plate in thermal communication with the first section of the chip, or the second plurality of cooling channels may be formed integrally with a second cold plate in thermal communication with the second section of the chip, or both. The device may also include a thermal interface material or porous structure between the first cold plate and the first section of the chip, or between the second cold plate and the second section of the chip, or both. The first plurality of cooling channels may be jet impingement channels, or the second plurality of cooling channels may be jet impingement channels, or both. The device may further include a vapor permeable membrane between the jet impingement channels and the porous member.

The cooling channels from the first plurality of flow channels may be parallel with each other, or the cooling channels from the second plurality of flow channels may be parallel with each other, or both.

The device may include a flow control device configured to adjust the flow rate of at least one channel from the first plurality of channels.

In a second aspect, the present invention may be generally characterized as providing a process for controlling a heat flux of an electronic chip by: passing a first portion of the cooling fluid through a first plurality of cooling channels; transferring heat from a first section of a chip having a first functionality to the first portion of the cooling fluid in the first plurality of cooling channels; passing a second portion of the cooling fluid through a second plurality of cooling channels; and, transferring heat from a second section of the chip, having a second functionality independent of the first functionality, to the second portion of the cooling fluid in the second plurality of cooling channels. A flow rate of the first portion of the cooling fluid in the first plurality of cooling channels may be adjusted independently from a flow rate of the second portion of the cooling fluid in the second plurality of cooling channels. The cooling fluid may be a two-phase cooling fluid or a single phase cooling fluid.

The process may also include monitoring a temperature of the first section of the chip, and adjusting, based on the temperature of the first section of the chip, the flow rate of the first portion of the cooling fluid through the first plurality of cooling channels. The process may also include monitoring a temperature of the second section of the chip, and adjusting, based on the temperature of the second section of the chip, the flow rate of the second portion of the cooling fluid through the second plurality of cooling channels.

The process may include monitoring an electrical power consumption, a heat flux map, or both of the first section of the chip, and adjusting, based on the electrical power consumption, the heat flux map, or both of the first section of the chip, the flow rate of the first portion of the cooling fluid through the first plurality of cooling channels. The process may also include monitoring an electrical power consumption, a heat flux map, or both of the second section of the chip, and adjusting, based on the electrical power consumption, the heat flux map, or both of the second section of the chip, the flow rate of the second portion of the cooling fluid through the second plurality of cooling channels.

The process may also include adjusting the flow rate of the first portion of the cooling fluid in the first plurality of cooling channels with a flow control device.

The process may include adjusting the flow rate of the second portion of the cooling fluid in the second plurality of cooling channels with a flow control device.

The process may include monitoring a pressure associated with a two-phase cooling fluid, and adjusting, based on the pressure, the flow rate of the first portion of the cooling fluid through the first plurality of cooling channels, or adjusting, based on the pressure, the flow rate of the second portion of the cooling fluid through the second plurality of cooling channels, or, adjusting, based on the pressure, both. The pressure may be a liquid pressure, a vapor pressure, or a liquid-vapor mixture pressure.

Additional aspects, embodiments, and details of the invention, all of which may be combinable in any manner, are set forth in the following detailed description of the invention.

### DETAILED DESCRIPTION OF THE DRAWINGS

One or more exemplary embodiments of the present invention will be described below in conjunction with the following drawing figures, in which:

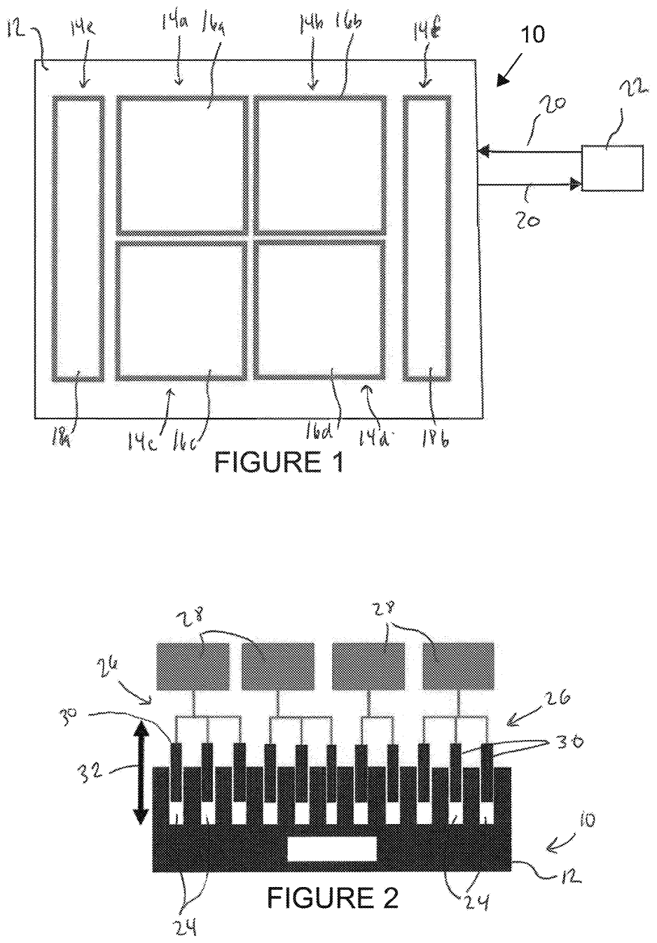

FIG. 1 shows a top view of exemplary electronic chip used in accordance with the present disclosure;

FIG. 2 shows a side schematic view of an example according to one or more aspects of the present disclosure;

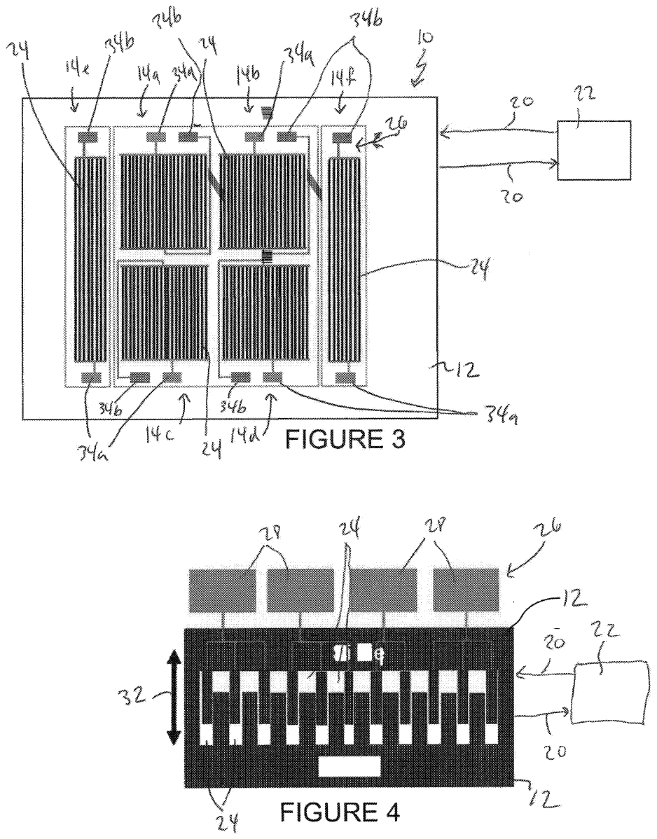

FIG. 3 shows a top schematic view of another example according to one or more aspects of the present disclosure;

FIG. 4 shows another side schematic view of an example according to one or more aspects of the present disclosure;

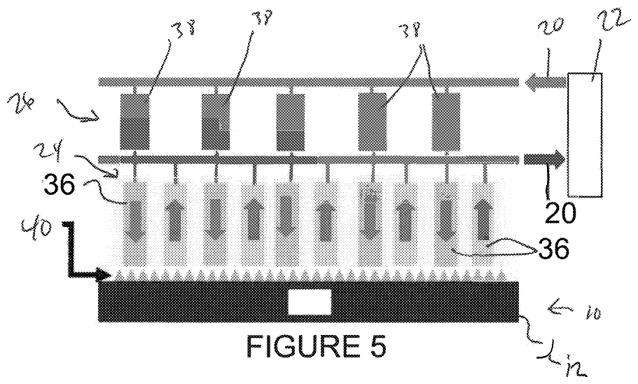

FIG. 5 shows a further side schematic view of an example according to one or more aspects of the present disclosure;

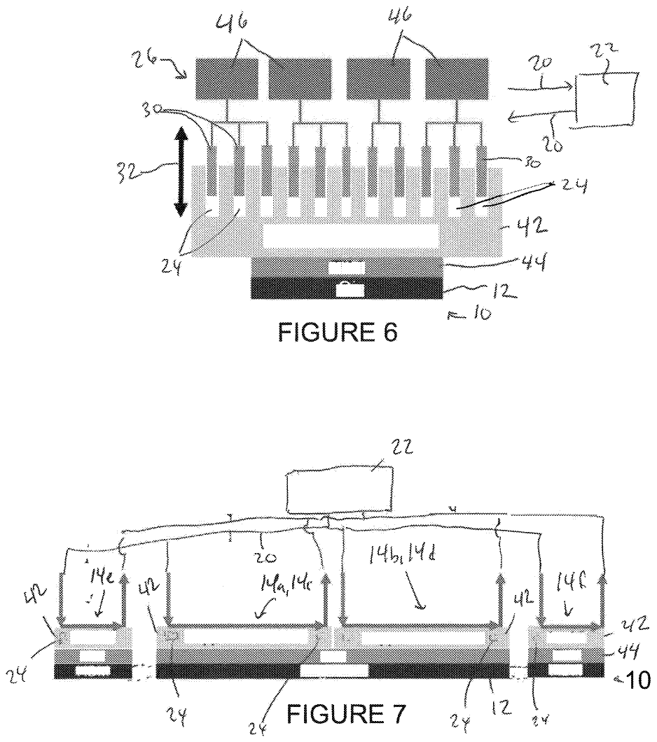

FIG. 6 shows a side schematic view of another example according to one or more aspects of the present disclosure;

FIG. 7 shows a side schematic view of a further example according to one or more aspects of the present disclosure;

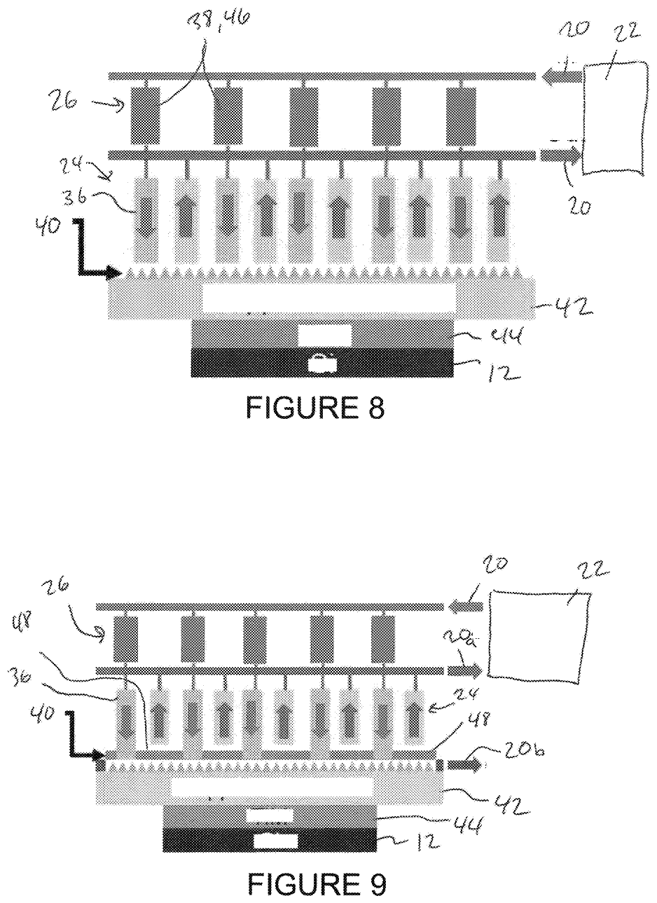

FIG. 8 shows a side schematic view of another example according to one or more aspects of the present disclosure;

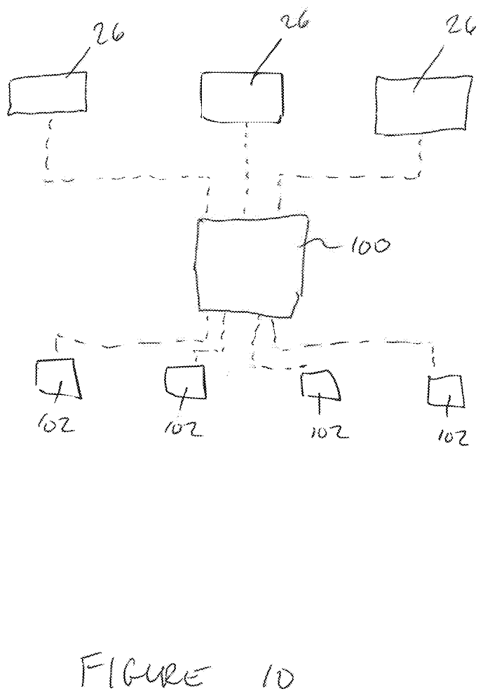

FIG. 9 shows another side schematic view of an example according to one or more aspects of the present disclosure;

FIG. 10 shows a schematic view of a system with a controller that may be used to implement one or more aspects of the present invention;

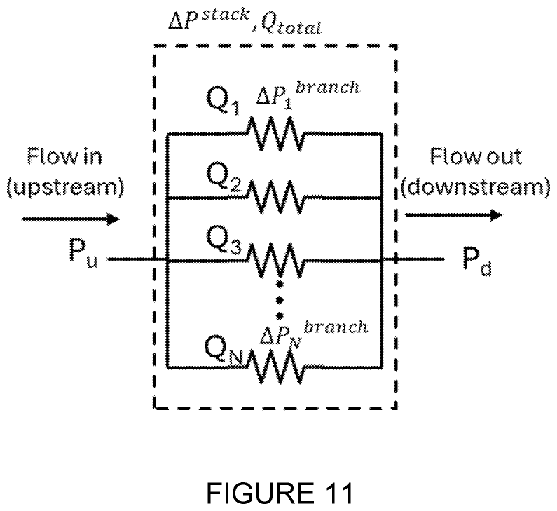

FIG. 11 is a schematic diagram of an example architecture according to one or more aspects of the present disclosure;

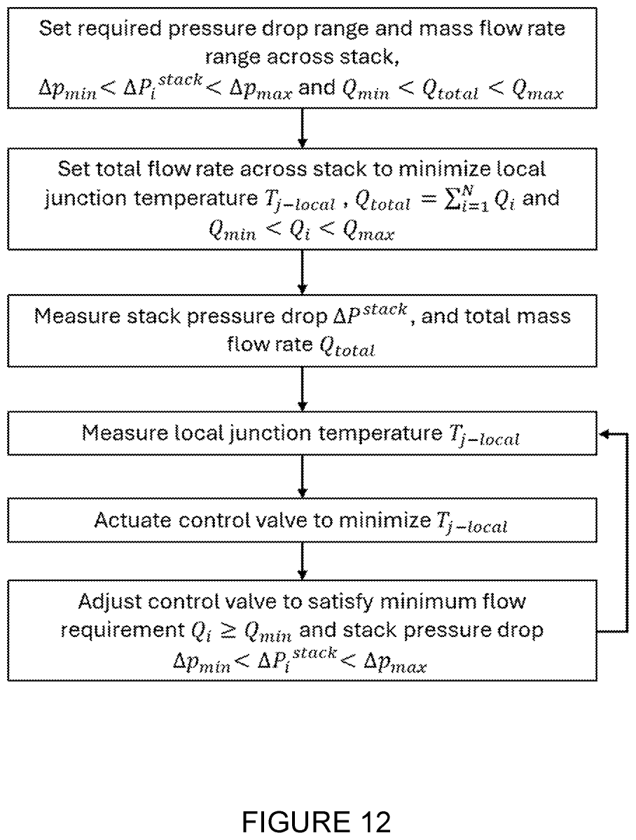

FIG. 12 is a flow diagram of an algorithm utilized in one or more aspects of the present disclosure;

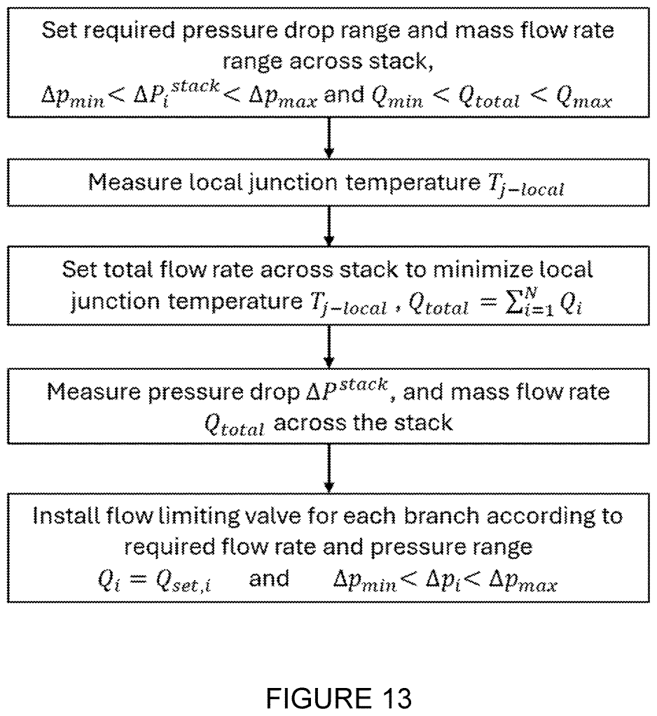

FIG. 13 is another flow diagram of an algorithm utilized in one or more aspects of the present disclosure;

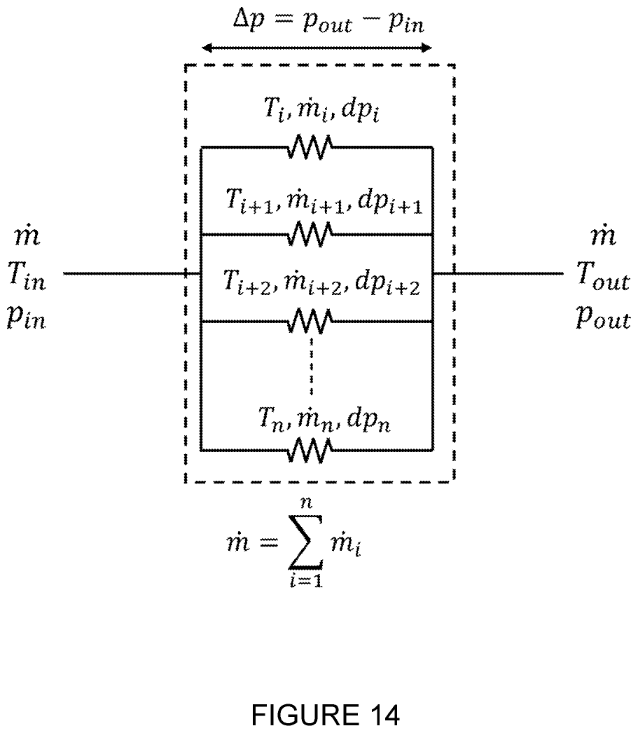

FIG. 14 is another schematic diagram of an example architecture according to one or more aspects of the present disclosure; and,

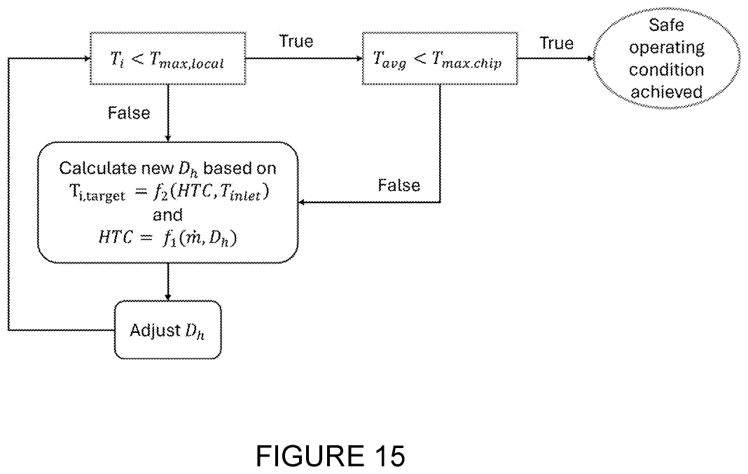

FIG. 15 is another flow diagram of an algorithm utilized in one or more aspects of the present disclosure.

It should be appreciated and understood by those of ordinary skill in the art that various other components such as valves, pumps, filters, heat exchangers, other electrical components, etc. were not shown in the drawings as it is believed that the specifics of same are well within the knowledge of those of ordinary skill in the art and a description of same is not necessary for practicing or understating the embodiments of the present invention. In general, the same reference numbers will be used throughout the drawing(s) and accompanying written description to refer to the same or like parts.

### DETAILED DESCRIPTION OF THE INVENTION

As mentioned above, processes and apparatuses for controlling a flow of a cooling fluid in response to a change in a temperature of an electronic device, such as a chip, have been invented. While a computational task is performed, heat is generated by conversation of electrical to thermal energy at transistors. Based on the chip architecture, the heat is distributed across the silicon die as background heat flux (uniform heat flux across the entire silicon die), or hotspots (high heat flux at a small region in a specific location on the silicon die). The thermal load on each region of the silicon depends on the computational task and how the software handles computational load distribution across the chip. As a result, the heat fluxes and hotspots are highly dynamic. This is because modern electronic chips utilize dynamic power scaling which adjusts power consumption based on workload intensity to handle various workloads while maintaining lowest power consumption. The ideal scenario is that the entire chip is utilized at 100% capacity, but in reality, the transient behavior cannot be avoided. Accordingly, this means the heat flux can switch from 10% at idle mode to 90+% in milliseconds while the entire chip or part of it is utilized based on the specific silicon die function. The chip thermal management system will respond to transient load via functions such as dynamic voltage and frequency scaling while utilizing load balancing, task scheduling, and other functions to minimize this impact.

The present disclosure contains designs and configurations that respond to transient loads across a heterogeneous integrated chip with multiple functional die sections or zones or with chiplets cooled by two-phase or single phase direct-to-chip systems. This disclosure adjusts local flow rate across chiplets or silicon die zones. Such local control mitigates the issues regarding transient and local thermal loads in direct-to-chip cold plates. This local control may be achieved via localized flow control paths that adjust the flow in a certain region. If the heat flux is low, the flow rate decreases. This will result in boiling initiation in the channel and achieving boiling heat transfer coefficients. The local flow rate may be adjusted based on embedded temperature sensors on the silicon die, and electrical power consumption at a certain region of the chip. If the power consumption and local temperature increase, then the local flow rate will increase to increase boiling heat transfer coefficient and avoid critical heat flux. This local control will enable spatial control of cooling across the heterogeneously integrated chip, and faster response to transient load variations. The present systems and processes may utilize a pump for refrigerant flow or may be without a pump for refrigerant flow.

With these general principles in mind, one or more embodiments of the present invention will be described with the understanding that the following description is not intended to be limiting.

Turning to FIG. 1, an exemplary electronic chip 10 includes printed circuit board (PCB) 12 having a plurality of zones 14a, 14b, 14c, 14d, 14e, 14f with silicon dies, or a portion thereof, or chiplets. In the electronic chip 10, there are four (4) zones, 14a, 14b, 14c, 14d that contain an individual processor 16a, 16b, 16c, 16d and there are two (2) zones 14e, 14f that each contain high bandwidth memory (HBM) 18a, 18b. Thus, each of the zones 14a, 14b, 14c, 14d, 14e, 14f has an individual functionality that may be the same as another zone 14a, 14b, 14c, 14d, 14e, 14f or it may be different. Additionally, the individual functionalities of the zones 14a, 14b, 14c, 14d, 14e, 14f may be independent of the other zones 14a, 14b, 14c, 14d, 14e, 14f. As discussed above, in certain zones 14a, 14b, 14c, 14d, 14e, 14f (or in different areas of the same zone 14a, 14b, 14c, 14d, 14e, 14f), the electronic chip 10 will have a high temperature at certain zones due to the operation of the chip 10. Accordingly, a two-phase cooling fluid 20 from a source 22, such as a tank, container or the like, may be provided to the chip 10. Exemplary two-phase cooling fluids 20 include R134a (1,1,1,2-tetrafluoroethane), R515B (a blend of R1234ze (trans-1,3,3,3-tetrafluoroprop-1-ene) and R227ea (heptafluoropropane)), and, R1233zd (trans-1-chloro-3,3,3-trifluoropropene). In some aspects, a single phase cooling fluid 20 may be used, such as water or a water-glycol mixture, including PG25.

As discussed above, the present disclosure provides designs and configurations that respond to heat fluxes across a heterogeneous integrated chip 10 with multiple functional die sections or zones 14a, 14b, 14c, 14d, 14e, 14f or with chiplets. Unlike current systems which merely generally control the entire flow of the cooling fluid 20 to the chip 10, the present disclosure provides for control to the individual sections or zones 14a, 14b, 14c, 14d, 14e, 14f, or subzones/subsections, to ensure that those sections or zones 14a, 14b, 14c, 14d, 14e, 14f with a high temperature receive sufficient cooling fluid 20. This results in a more efficient use of the cooling fluid 20, and allows for a more efficient use of the chip 10.

Turning to FIG. 2, a first example according to the present disclosure is depicted. In this example, channels 24 are etched on the back of the silicon die 12 using semiconductor manufacturing methods. By “channels” 24 it is merely meant that fluid passageways for the cooling fluid 20 are formed. The etching could be done directly on back of the silicon die 12, or it could be done on a passive silicon die 12 and then the passive silicon die 12 is bonded to the silicon die 12 using direct silicon-to-silicon bonding technologies. The channels 24 may be parallel with other channels or include one or more sections that are parallel with other sections or channels.

The channels 24 may be divided into different groups or pluralities. The number of channels 24 in each group may be the same or different. Additionally, the size of the channels 24 in each group may be the same or different.

According to the various designs, a flow rate of a portion of the cooling fluid 20 in a first plurality of cooling channels 24 is configured to be controlled independently from a flow rate of a second portion of the cooling fluid 20 in a second plurality of cooling channels 24. In other words, a flow rate of the cooling fluid 20 in each of the channels 24 or different groups of channels 24 can be controlled or adjusted independently of the flow rate of the fluid 20 in the channels 24 of the other groups. This allows for a more precise flow of cooling fluid 20 to those sections or zones 14a, 14b, 14c, 14d, 14e, 14f that have a higher temperature. The flow rate may be measured as a mass flow rate or a volume flow rate.

To adjust a flow rate of the fluid 20 in the channels 24, flow control devices 26 may be used. For example, MEMS actuators 28 may be provided to move a wall 30 in the directions of arrow 32 to adjust a size of one or more of the channels 24. Local vapor quality and pressure may be utilized as alternative or additional measure to adjust the flow rate.

Turning to FIG. 3, another example is shown in which the channels 24 are divided into groups corresponding to each of the zones 14a, 14b, 14c, 14d, 14e, 14f of the chip 10. The flow control devices 26 may be actuators 34a, 34b used with, for example, a valve, one actuator 34a for an inlet and one actuator 34b for an outlet, are provided for each zone 14a, 14b, 14c, 14d, 14e, 14f so that the flow rate of the cooling fluid 20 to a group of channels 24 for a particular zone 14a, 14b, 14c, 14d, 14e, 14f may be controlled independently from the channels 24 of other zones 14a, 14b, 14c, 14d, 14e, 14f.

Turning to FIG. 4, an example with a 3D chip is depicted. In the 3D chip, at least two silicon dies 12 are stacked on top of each other. In order to transfer the heat out from the middle or bottom die, the channels 24 are formed between the two silicon dies 12. These channels 24 can be formed by semiconductor etching and bonding techniques. The flow rate in these channels 24 can be adjusted with flow control devices 26 such as the MEMS actuators 28, similar to FIG. 2.

With reference to FIG. 5, in this example, cooling fluid 20 is provided with vertical flow channels 24 which comprise jet impingement channels 36 configured. The vertical flow channels 24 are parallel with each other. Each jet impingement channels 36 or group of jet impingement channels 36 may have a flow control device 26, such as an electronic needle valve 38, which adjusts the flow rate and jet velocity. The outlet flow may or may not have a flow control device 26 based on the implemented design and pressure difference across the inlet and outlet channels.

Additionally, as depicted in FIG. 5, a porous member or structure 40 is provided on the silicon die 12, between the silicon die 12 and the jet impingement channels 36, to induce capillary flow across the surface of the silicon die 12 and prevent backflow of vapor into the inlet jet impingement channels 36. The wicking properties of the porous structure 40 may be adjusted in order to redirect the vapor to the outlet channels 24. The porous member 40 on the back of the silicon die 12 may be formed by various additive and subtractive techniques. This includes but not limited to interlayer bonding, silicon etching, selective laser melting, electrochemical additive manufacturing (ECAM), to name a few. Moreover, although not depicted as such, it is expressly contemplated that the porous member 40 is provided in any of the examples described herein, including the examples of FIGS. 2 to 4. Additionally, in systems with a single phase cooling fluid, the porous element 40 may not be included and is preferably not provided.

Turning to FIG. 6, in this example, a cold plate 42 is installed on top of the silicon, with or without a thermal interface material (TIM) 44 (such as indium foil, phase change material, thermal grease, graphite sheet, to name a few). The cold plate 42 may be manufactured from copper, other metals, alloys, ceramics, metal or non-metal composites, or any other suitable material.

The difference between this example and the example in FIG. 2 is that in FIG. 2, the channels 24 are formed directly on the silicon die 12. In the example of FIG. 6, the silicon die 12 does not include the channels 24, instead, the channels 24 are provided in the cold plate 42. This implementation has the benefit of less complexity and associated cost and possibly higher reliability as it eliminates the silicon microfabrication techniques. However, the thermal resistances associated with the TIM 44 and the copper cold plate 42 will be added.

The device may include flow control devices 26 such as piezoelectric actuators 46 or electronic needle valves to control flow rates of the cooling fluid 20 through the channels 24. Again, this may be accomplished by moving a wall 30, baffle, or other structure in the direction of arrow 32 to change a size of the channels 24.

As shown in FIG. 7, another example of the present disclosure depicts multiple cold plates 42 which can be provided for each zone 14a, 14b, 14c, 14d, 14e, 14f. Thus, similar to FIG. 3, it is possible to have flow control mechanism on a single channel 24 or a zone 14a, 14b, 14c, 14d, 14e, 14f of channels 24. Also, it is possible to have a single cold plate 42 with multiple flow zones 14a, 14b, 14c, 14d, 14e, 14f, or multiple cold plates 42. This example is similar to the example in FIG. 3 with the difference being the channels 24 are formed in the cold plates 42—not the silicon die 12.

Turning to FIG. 8, this example is similar to FIG. 5, but instead of etching or deposition of porous structure 40 on the back of the silicon die 12, the etching or deposition of the porous structure 40 in FIG. 8 is performed on the cold plate 42, and the cold plate 42 is positioned between the manifold for the jet impingement channels 36 and the silicon die 12. Thus, in this example, the silicon die 12 does not include the jet impingement channels 36 or any porous structures 40. Again, the copper cold plate 42 may or may not be installed on top of the silicon die with the TIM 44.

Since the cold plate 42 is implemented instead of silicon etching, it is possible to use larger flow control devices 26 such as electronic needle valves 38 and/or piezoelectric actuators 46 instead of MEMS actuators 28. However, this is merely preferred and not required.

Since the silicon die 12 is not manufactured or directly processed to include the channels 24, 36, this example provides a lower cost, higher reliability, and lower complexity. However, similar to Example 4, thermal resistances associated with the TIM 44 and the copper cold plate 42 may impact the design.

Finally, in FIG. 9 another example is shown which provides a vapor permeable membrane 48 proximate the outlet channels 24 to redirect any excess liquid and act as phase separator. Thus, only vapor will rise, pass through the vapor permeable membrane 48, and out the outlet channels in stream 20a. Any excess cooling fluid 20 present as liquid can flow out a separate outlet in stream 20b.

In any of the foregoing examples, a flow rate through the channels 24, 36 is adjusted with a flow control device 26 like the MEMS actuators 28, the electronic needle valves 38, and the piezoelectric actuators 46. As shown in FIG. 10, such flow control devices 26 can be in electronic communication with a controller 100. The controller 100 may be in electronic communication with one or more thermal sensors or probes 102 which provide information relating to the temperature of one or more zones 14a, 14b, 14c, 14d, 14e, 14f or sections of the chip 10 to the controller 100. Based on the received information, the controller 100 may send electronic signals to the flow control device 26 in order to adjust the flow rate of the cooling fluid 20 through the channels 24, 36. In addition to, or instead of monitoring temperatures, the controller 100 may send signals to the flow control device 26 to adjust the flow rate of the cooling fluid 20 through the channels 24, 36 based on power consumption of various zones 14a, 14b, 14c, 14d, 14e, 14f or sections of the chip 10. Although depicted with flow control on the inlets of the channels, in addition to or as an alternative to this, it is contemplated that flow control may be associated with the outlet of the channels.

It is also contemplated that the flow control device 26 do not react and adjust based on an active signal, but instead, the flow control devices 26 may adjust a flow rate of the cooling fluid 20 based on a passive signal. For example, the flow control device 26 may include one or more components that react to temperatures. If the temperature reaches a level, the component may react and adjust an opening for a channel 24, 36, or a size of the channel 24, 36. For example, a spring may be made from a metal which expands at a temperature. In response to portions of the chip 10 that are in thermal communication with the spring reaching that temperature, the spring will expand and can move a structure like the wall 30, baffle, portal, etc. to adjust a flow rate of the cooling fluid 20 based on the temperature. It is also contemplated that the flow control device 26 may include one or more components that react to a pressure of the liquid and/or vapor. In other words, if a pressure associated with the following fluid 20 reaches a certain pressure or a pressure threshold (increased pressure or decreased pressure), the flow control device 26 changes to allow, prohibit, or change a flow.

Any of the channels, zones, sections or other similar components may be equipped with one or more monitoring components including sensors, measurement devices, data capture devices or data transmission devices. Signals, process or status measurements, and data from monitoring components may be used to monitor conditions in, around, and on process equipment. Signals, measurements, and/or data generated or recorded by monitoring components may be collected, processed, and/or transmitted through one or more networks or connections that may be private or public, general or specific, direct or indirect, wired or wireless, encrypted or not encrypted, and/or combination(s) thereof; the specification is not intended to be limiting in this respect.

Signals, measurements, and/or data generated or recorded by monitoring components may be transmitted to one or more computing devices or systems, such as controller 100. Computing devices or systems may include at least one processor and memory storing computer-readable instructions that, when executed by the at least one processor, cause the one or more computing devices to perform a process that may include one or more steps. For example, the one or more computing devices may be configured to receive, from one or more monitoring component, data related to at least one piece of equipment associated with the process. The one or more computing devices or systems may be configured to analyze the data. Based on analyzing the data, the one or more computing devices or systems may be configured to determine one or more recommended adjustments to one or more parameters of one or more processes described herein. The one or more computing devices or systems may be configured to transmit encrypted or unencrypted data that includes the one or more recommended adjustments to the one or more parameters of the one or more processes described herein.

The systems and devices described herein may include a controller or a computing device comprising a processing unit and a memory which has stored therein computer-executable instructions for implementing the processes described herein. The processing unit may comprise any suitable devices configured to cause a series of steps to be performed so as to implement the method such that instructions, when executed by the computing device or other programmable apparatus, may cause the functions/acts/steps specified in the methods described herein to be executed. The processing unit may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory may be any suitable known or other machine-readable storage medium. The memory may comprise non-transitory computer readable storage medium such as, for example, but not limited to, an electronic, magnetic, optical, electromagnetic, infrared, or semiconductor system, apparatus, or device, or any suitable combination of the foregoing. The memory may include a suitable combination of any type of computer memory that is located either internally or externally to the device such as, for example, random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. The memory may comprise any storage means (e.g., devices) suitable for retrievably storing the computer-executable instructions executable by processing unit.

The methods and systems described herein may be implemented in a high-level procedural or object-oriented programming or scripting language, or a combination thereof, to communicate with or assist in the operation of the controller or computing device. Alternatively, the methods and systems described herein may be implemented in assembly or machine language. The language may be a compiled or interpreted language. Program code for implementing the methods and systems described herein may be stored on the storage media or the device, for example a ROM, a magnetic disk, an optical disc, a flash drive, or any other suitable storage media or device. The program code may be readable by a general or special-purpose programmable computer for configuring and operating the computer when the storage media or device is read by the computer to perform the procedures described herein.

Computer-executable instructions may be in many forms, including modules, executed by one or more computers or other devices. Generally, modules include routines, programs, objects, components, data structures, etc., that perform particular tasks or implement particular abstract data types. Typically, the functionality of the modules may be combined or distributed as desired in various embodiments.

It will be appreciated that the systems and devices and components thereof may utilize communication through any of various network protocols such as TCP/IP, Ethernet, FTP, HTTP and the like, and/or through various wireless communication technologies such as GSM, CDMA, Wi-Fi, and WiMAX, is and the various computing devices described herein may be configured to communicate using any of these network protocols or technologies.

### Active Control Algorithm for Two-Phase Using Flow Rate and Pressure Regulation

Considering N-branch parallel flow system with an inlet manifold and outlet manifold. See, FIG. 11. Upstream node pressure is Pᵤ, and downstream node pressure is P_{d}. The stack pressure drop is:

ΔP^{stack}=Pᵤ−P_{d}

This is the pressure drop between manifolds.

Each branch carries its own mass flow rate Q₁, Q₂, Q₃, . . . , Q_{N}.

The system enforces a constant total mass flow:

Qₜₒₜₐₗ=Q₁+Q₂+Q₃+ . . . +Q_{N}

This constraint for Qₜₒₜₐₗ is maintained by a pump controller or a higher-level flow controller.

Each branch contains at least two hydraulic elements including a flow control mechanism like a valve, and a heated channel. The pressure drop of the branch is

ΔPᵢ^{branch}=ΔP_{v,i}+Δp_{ch,i}

Where

Δp_{ch,i}=channel pressure drop

ΔP_{v,i}=valve(flow control mechanism)pressure drop

In this case the control valve responds based on the pressure of the branch.

The total pressure drop across every full branch is identical:

ΔP₁^{branch}=ΔP₂^{branch}=ΔP₃^{branch}= . . . =ΔP_{N}^{branch}

Thus

ΔP^{stack}=ΔPᵢ^{branch}

The heated channel constitutive relation

Δp_{ch,i}=Fᵢ(Qᵢ,stateᵢ)

Where stateᵢ can be single-phase liquid or two-phase flow depending on thermal conditions.

Each control valve provides an adjustable flow rate and pressure drop.

Δp_{v,i}=Vᵢ(Qᵢ,uᵢ)

Where uᵢ is valve position. By adjusting the uᵢ the controller changes the valve position and branch flow.

The branch governing equation consists of

ΔP=Vᵢ(Qᵢ,uᵢ)+Fᵢ(Qᵢ,stateᵢ)

This equation holds for each branch i.

The branch flows are actively controlled while the total system flow rate remains constant. The controller therefore enforces:

Qᵢ=Qᵢ*

Subject to

$${\sum }_{i = 1}^{N} {Q}_{i}^{*} = {Q}_{total}$$

The valves automatically adjust to satisfy the branch equations. The valve controller is adjusted for a minimum flow rate in each branch.

Qᵢ≥Qₘᵢₙ

Minimum mass flow rate is specified experimentally according to cooling requirement at uniform heat flux across the chip at idle state.

In order to solve for branch pressure drop, for a given branch flow rate Qᵢ, the required valve pressure drop becomes

Δp_{v,i}=ΔP^{stack}−Δp_{ch,i}

Or

Δp_{v,i}=ΔP^{stack}−Fᵢ(Qᵢ,stateᵢ)

The valve compensates for any change in the channel pressure fluctuation based on vapor generation.

When boiling occurs in channel i, pressure drop in the channel may increase:

ΔP_{v,i}=ΔP^{stack}−Δp_{ch,i}

As a result pressure drop in the valve should decrease to maintain constant ΔP^{stack}. This occurs by valve opening.

Pressure drop is measured across the stack via a pressure sensor. Total mass flow rate is measured entering to the stack via a sensor such as ultrasonic flow meter. Junction temperature is measured locally T_{j-local}. The actuator valve adjusts to minimize the local junction temperature.

The algorithm in FIG. 12 is implemented.

### Passive Control Algorithm for Two-Phases Using Flow Rate and Pressure Regulation

Considering N-branch parallel flow system with an inlet manifold and outlet manifold. See, FIG. 11. Upstream node pressure is Pᵤ, and downstream node pressure is P_{d}

The stack pressure drop is:

ΔP^{stack}=Pᵤ−P_{d}

This is the pressure drop between manifolds.

Each branch carries its own flow rate Q₁, Q₂, Q₃, . . . , Q_{N}.

The system enforces a constant total flow:

Qₜₒₜₐₗ=Q₁+Q₂+Q₃+ . . . +Q_{N}

This constraint for Qₜₒₜₐₗ is maintained by a pump controller or a higher-level flow controller.

Flow limiting valves can be used as a tool for passive control. Flow-limiting valve automatically adjusts the internal opening so that

Qᵢ=Q_{set,i}

The valve enforces constant mass flow for a pressure change within the valve pressure design envelope. Internally, the valve continuously changes its hydraulic resistance so the mass flow stays constant.

The branch equation is

ΔPᵢ^{branch}=ΔP_{v,i}+Δp_{ch,i}

The valve enforces the constant mass flow condition in the branch

Qᵢ=Q_{set,i}

The heated channel constitutive relation

Δp_{ch,i}=Fᵢ(Qᵢ,stateᵢ)

Where stateᵢ can be single-phase liquid or two-phase flow depending on thermal conditions.

The valve pressure drop becomes whatever value that satisfied the branch pressure balance:

Δp_{v,i}=ΔP^{stack}−Fᵢ(Qᵢ,stateᵢ)

The key is design the flow limiting valve to operate within minimum and maximum pressure drop for single phase and two-phase flow regime inside the branch:

Δpₘᵢₙ<Δp_{v,i}<Δpₘₐₓ

The valve automatically enforces flow control Qᵢ to maintain a set constant mass flow rate Q_{set,i} according to flow pressure drop inside the branch. The Δpₘᵢₙ and Δpₘₐₓ is designed for the flow limiting valve according to the pressure limits.

The algorithm in FIG. 13 is implemented.

### Active Control Algorithm for Single-Phase Flow by Modulating Flow Rate Distribution

The closed loop control algorithm tracks temperature using a thermal sensing device within the electronic chip whose signal is read by an external flow control device. Upon sensing a rise in temperature beyond the prescribed local limit T_{max,local}, the actuator devices trigger a change in channel height which in turn affects the thermal-hydraulic interactions within a flow cooling microchannel.

For example, consider a cold plate with n parallel channels each with an associated mass flow rate m and pressure drop dpᵢ. See, FIG. 14. Within each channel there exists a temperature sensor or series of temperature sensors outputting Tᵢ that acts as the input value monitored by the flow actuation system.

Where,
\dot{m}=total mass flow rate
\dot{m}ᵢ=local mass flow rate in a channel
Tᵢₙ=cold plate fluid inlet temperature
Tₒᵤₜ=cold plate fluid outlet temperature
Tᵢ=local die temperature
Δp=overall cold plate pressure drop
pᵢ=local pressure drop in a channel

In this flow modulation scheme, the total flow rate m and overall pressure drop Δp remain constant. Modifying a channel where an over-temperature T_{max,local} is sensed must not result in an over-temperature in a separate channel; therefore, the average temperature of all sensors must also be an added constraint to the objective function.

Tᵢ<T_{max,local}

T_{avg}=average(Tᵢ,Tᵢ₊₁,Tᵢ₊₂, . . . ,Tₙ)<T_{max,chip}

The magnitude of the control response, that is the amount by which the microchannel dimension is modulated by the MEMS actuation, is determined according to the cooling required by the new detected heat load and over-temperature. The local heat transfer coefficient HTC in a single channel is a function of the flow rate, channel dimensions, and fluid thermophysical properties (density, viscosity, heat capacity, thermal conductivity). Since the fluid thermophysical properties remain constant in the single-phase regime, the control mechanism needs only to account for changes in flow rate and channel dimensions when responding to temperature rise. The channel can be characterized according to its Dₕ such that HTC is a function ƒ₁ of both mass flow rate and hydraulic diameter.

HTC=f₁(\dot{m},Dₕ)

Tᵢ,target=f₂(HTC,Tᵢₙₗₑₜ)

The solver for HTC and T_{i,target} can use user-prescribed temperatures, channel sizes, mass flow rates, and/or local fluid velocity as the function constraints.

The resulting continuous procedure for modulating chip temperature and flow rate is then implemented based on the flow diagram shown in FIG. 15.

The previous flow control method can also be followed when using valves for flow control. In this scheme, the overall mass flow rate in the cold plate can change in addition to the flow rate in individual channels. HTC and chip temperature remain a function of the mass flow rate, hydraulic diameter, and inlet coolant temperature, and the algorithm shown in FIG. 15 can be followed, where mass flow rate can be adjusted instead of or in addition to hydraulic diameter.

### Example 1

A device according to FIG. 2 is prepared by providing channels in a surface of a silicon die having multiple functionality sections with an etching process. Moveable walls are provided for each channel, and each wall moves because of an associated MEMS actuator. A reservoir of R134a as a cooling fluid is provided and fluidically connected to the channels. A pump circulates the fluid from the reservoir to the channels. In the channels, the fluid absorbs heat from the different functionality sections of the silicon die.

A high heat flux associated with the silicon die opposite the left-most channel in FIG. 2 is detected by a controller in communication with a thermal sensor. A signal is sent by the controller to the MEMS actuator associated with the left-most channel in FIG. 2 to move the wall in this channel to increase a flow rate of the cooling fluid therein. After the increased flow of cooling fluid, the thermal sensor indicates a reduced temperature on the silicon die opposite the left-most channel in FIG. 2.

### Example 2

Example 1 is repeated with R515B as the cooling fluid.

After the increased flow of cooling fluid, the thermal sensor indicates a reduced temperature on the silicon die opposite the left-most channel in FIG. 2.

### Example 3

Example 1 is repeated with R1233zd as the cooling fluid.

After the increased flow of cooling fluid, the thermal sensor indicates a reduced temperature on the silicon die opposite the left-most channel in FIG. 2.

### Example 4

A device according to FIG. 3 is prepared by providing channels in a surface of a silicon die having multiple functionality sections with an etching and bonding process. Each functionality section has its own set or group of channels. An inlet valve is provided for each group of channels. A reservoir of R134a as a cooling fluid is provided and fluidically connected to the inlet valves. A pump circulates the fluid from the reservoir, through the inlet valves, and to the channels. In the channels, the fluid absorbs heat from the different functionality sections of the silicon die.

A high heat flux associated with section 14b in FIG. 3 is detected by a controller in communication with a thermal sensor. A signal is sent by the controller to the inlet valve associated with the channels of section 14b in FIG. 3 to open the valve to increase a flow rate of the cooling fluid therethrough. After the increased flow of cooling fluid, the thermal sensor indicates a reduced temperature at section 14b of the silicon die in FIG. 3.

### Example 5

Example 4 is repeated with R515B as the cooling fluid.

After the increased flow of cooling fluid, the thermal sensor indicates a reduced temperature at section 14b of the silicon die in FIG. 3.

### Example 6

Example 4 is repeated with R1233zd as the cooling fluid.

After the increased flow of cooling fluid, the thermal sensor indicates a reduced temperature at section 14b of the silicon die in FIG. 3.

### Example 7

A device according to FIG. 4 is prepared by providing channels in surfaces of two silicon dies having multiple functionality sections with an etching process. The two surfaces with the channels of the two silicon dies are attached to each other using a bonding process. Moveable walls are provided for each channel, and each wall moves because of an associated MEMS actuator. A reservoir of R134a as a cooling fluid is provided and fluidically connected to the channels. A pump circulates the fluid from the reservoir to the channels. In the channels, the fluid absorbs heat from the different functionality sections of the two silicon dies.

A high heat flux associated with the upper silicon die proximate the right-most channel in FIG. 4 is detected by a controller in communication with a thermal sensor. A signal is sent by the controller to the MEMS actuator associated with the right-most channel in FIG. 4 to move the wall in this channel to increase a flow rate of the cooling fluid therein. After the increased flow of cooling fluid, the thermal sensor indicates a reduced temperature on the upper silicon die proximate the right-most channel in FIG. 4.

### Example 8

Example 7 is repeated with R515B as the cooling fluid.

After the increased flow of cooling fluid, the thermal sensor indicates a reduced temperature on the upper silicon die proximate the right-most channel in FIG. 4.

### Example 9

Example 7 is repeated with R1233zd as the cooling fluid.

After the increased flow of cooling fluid, the thermal sensor indicates a reduced temperature on the upper silicon die proximate the right most-channel in FIG. 4.

### Example 10

A device according to FIG. 5 is prepared by providing jet impingement channels above a silicon die having multiple functionality sections. Each jet impingement channel is in fluid communication with an electronic needle valve. A reservoir of R134a as a cooling fluid is provided and fluidically connected to the electronic needle valves. A plurality of outlet channels are also provided above the silicon die. The outlet channels are also fluidically connected to the reservoir of cooling fluid. A pump circulates the fluid from the reservoir to the channels. In the channels, the cooling fluid is impinged onto the silicon die and absorbs heat from the different functionality sections of the silicon die.

A high heat flux associated with the silicon die proximate the middle jet impingement channel in FIG. 5 is detected by a controller in communication with a thermal sensor. A signal is sent by the controller to the electronic needle valve associated with the middle channel in FIG. 5 to increase a flow rate of the cooling fluid therethrough. After the increased flow of cooling fluid, the thermal sensor indicates a reduced temperature on the silicon die proximate the middle channel in FIG. 5.

### Example 11

Example 10 is repeated with R515B as the cooling fluid.

After the increased flow of cooling fluid, the thermal sensor indicates a reduced temperature on the silicon die proximate the middle channel in FIG. 5.

### Example 12

Example 10 is repeated with R1233zd as the cooling fluid.

After the increased flow of cooling fluid, the thermal sensor indicates a reduced temperature on the silicon die proximate the middle channel in FIG. 5.

### Example 13

Example 10 is repeated with a porous member provided between the silicon die and the jet impingement channels.

After the increased flow of cooling fluid, the thermal sensor indicates a reduced temperature on the silicon die proximate the middle channel in FIG. 5.

### Example 14

Example 13 is repeated with R515B as the cooling fluid.

After the increased flow of cooling fluid, the thermal sensor indicates a reduced temperature on the silicon die proximate the middle channel in FIG. 5.

### Example 15

Example 13 is repeated with R1233zd as the cooling fluid.

After the increased flow of cooling fluid, the thermal sensor indicates a reduced temperature on the silicon die proximate the middle channel in FIG. 5.

### Example 16

A device according to FIG. 6 is prepared by providing channels in a surface of a cold plate with a machining process. Moveable walls are provided for each channel, and each wall moves because of an associated piezoelectric actuator. A silicon die with multiple functionality sections is in thermal communication with a surface of the cold plate opposite the surface of the cold plate with the channels. A reservoir of R134a as a cooling fluid is provided and fluidically connected to the channels. A pump circulates the fluid from the reservoir to the channels. In the channels, the fluid absorbs heat from the different functionality sections of the silicon die.

A high heat flux associated with the silicon die opposite the fourth from the left side channel in FIG. 6 is detected by a controller in communication with a thermal sensor. A signal is sent by the controller to the MEMS actuator associated with the fourth from the left side channel in FIG. 6 to move the wall in this channel to increase a flow rate of the cooling fluid therein. After the increased flow of cooling fluid, the thermal sensor indicates a reduced temperature on the silicon die opposite the fourth from the left side channel in FIG. 6.

### Example 17

Example 16 is repeated with R515B as the cooling fluid.

After the increased flow of cooling fluid, the thermal sensor indicates a reduced temperature on the silicon die opposite the fourth from the left side channel in FIG. 6.

### Example 18

Example 16 is repeated with R1233zd as the cooling fluid.

After the increased flow of cooling fluid, the thermal sensor indicates a reduced temperature on the silicon die opposite the fourth from the left side channel in FIG. 6.

### Example 19

Example 16 is repeated with an indium foil thermal interface material provided between the silicon die and the cold plate.

After the increased flow of cooling fluid, the thermal sensor indicates a reduced temperature on the silicon die opposite the fourth from the left side channel in FIG. 6.

### Example 20

Example 19 is repeated with R515B as the cooling fluid.

After the increased flow of cooling fluid, the thermal sensor indicates a reduced temperature on the silicon die opposite the fourth from the left side channel in FIG. 6.

### Example 21

Example 20 is repeated with R1233zd as the cooling fluid.

After the increased flow of cooling fluid, the thermal sensor indicates a reduced temperature on the silicon die opposite the fourth from the left side channel in FIG. 6.

### Example 22

A device according to FIG. 7 is prepared by providing channels in a surface of a cold plate with an additive manufacturing process. A silicon die with multiple functionality sections is in thermal communication with a surface of the cold plate opposite the surface of the cold plate having the channels. Each functionality section has its own group of channels. An outlet valve is provided for each group of channels. A reservoir of R134a as a cooling fluid is provided and fluidically connected to the outlet valves. A pump circulates the fluid from the reservoir, to the channels, and back through the outlet valves after passing fluid process stages to the reservoir. In the channels, the fluid absorbs heat from the different functionality sections of the silicon die.

A high heat flux associated with section 14f in FIG. 7 is detected by a controller in communication with a thermal sensor. A signal is sent by the controller to the outlet valve associated with the channels of section 14f in FIG. 7 to open the valve to increase a flow rate of the cooling fluid therethrough. After the increased flow of cooling fluid, the thermal sensor indicates a reduced temperature at section 14f of the silicon die in FIG. 7.

### Example 23

Example 22 is repeated with R515B as the cooling fluid.

After the increased flow of cooling fluid, the thermal sensor indicates a reduced temperature at section 14f of the silicon die in FIG. 7.

### Example 24

Example 22 is repeated with R1233zd as the cooling fluid.

After the increased flow of cooling fluid, the thermal sensor indicates a reduced temperature at section 14f of the silicon die in FIG. 7.

### Example 25

Example 22 is repeated with an PTM7950 phase change material as thermal interface material provided between the silicon die and the cold plate.

### Example 26

Example 25 is repeated with R515B as the cooling fluid.

After the increased flow of cooling fluid, the thermal sensor indicates a reduced temperature at section 14f of the silicon die in FIG. 7.

### Example 27

Example 25 is repeated with R1233zd as the cooling fluid.

After the increased flow of cooling fluid, the thermal sensor indicates a reduced temperature at section 14f of the silicon die in FIG. 7.

### Example 28

A device according to FIG. 8 is prepared by providing jet impingement channels above a cold plate. A silicon die with multiple functionality sections is in thermal communication with a surface of the cold plate opposite the surface of the cold plate having the channels. Each jet impingement channel is in fluid communication with an electronic needle valve. A reservoir of R134a as a cooling fluid is provided and fluidically connected to the electronic needle valves. A plurality of outlet channels are also provided above the silicon die. The outlet channels are fluidically connected to the reservoir of cooling fluid. A pump circulates the fluid from the reservoir to the channels. From the jet impingement channels, the cooling fluid is impinged onto the cold plate and absorbs heat from the different functionality sections of the silicon die.

A high heat flux associated with the silicon die proximate the middle jet impingement channel in FIG. 8 is detected by a controller in communication with a thermal sensor. A signal is sent by the controller to the electronic needle valve associated with the middle channel in FIG. 8 to increase a flow rate of the cooling fluid therethrough. After the increased flow of cooling fluid, the thermal sensor indicates a reduced temperature on the silicon die proximate the middle channel in FIG. 8.

### Example 29

Example 28 is repeated with R515B as the cooling fluid.

After the increased flow of cooling fluid, the thermal sensor indicates a reduced temperature on the silicon die proximate the middle channel in FIG. 8.

### Example 30

Example 28 is repeated with R1233zd as the cooling fluid.

After the increased flow of cooling fluid, the thermal sensor indicates a reduced temperature on the silicon die proximate the middle channel in FIG. 8.

### Example 31

Example 28 is repeated with an indium foil thermal interface material provided between the silicon die and the cold plate.

After the increased flow of cooling fluid, the thermal sensor indicates a reduced temperature on the silicon die proximate the middle channel in FIG. 8.

### Example 32

Example 31 is repeated with R515B as the cooling fluid.

After the increased flow of cooling fluid, the thermal sensor indicates a reduced temperature on the silicon die proximate the middle channel in FIG. 8.

### Example 33

Example 31 is repeated with R1233zd as the cooling fluid.

After the increased flow of cooling fluid, the thermal sensor indicates a reduced temperature on the silicon die proximate the middle channel in FIG. 8.

### Example 34

Example 31 is repeated with a porous member provided between the silicon die and the jet impingement channels. The porous section directs the liquid-vapor mixture towards exit channels in the cold plate.

After the increased flow of cooling fluid, the thermal sensor indicates a reduced temperature on the silicon die proximate the middle channel in FIG. 8.

### Example 35

Example 34 is repeated with R515B as the cooling fluid.

After the increased flow of cooling fluid, the thermal sensor indicates a reduced temperature on the silicon die proximate the middle channel in FIG. 8.

### Example 36

Example 34 is repeated with R1233zd as the cooling fluid.

After the increased flow of cooling fluid, the thermal sensor indicates a reduced temperature on the silicon die proximate the middle channel in FIG. 8.

### Example 37

Example 28 is repeated with a porous member provided between the silicon die and the jet impingement channels. The porous section directs the liquid-vapor mixture towards exit channels in the cold plate.

After the increased flow of cooling fluid, the thermal sensor indicates a reduced temperature on the silicon die proximate the middle channel in FIG. 8.

### Example 38

Example 37 is repeated with R515B as the cooling fluid.

After the increased flow of cooling fluid, the thermal sensor indicates a reduced temperature on the silicon die proximate the middle channel in FIG. 8.

### Example 39

Example 37 is repeated with R1233zd as the cooling fluid.

After the increased flow of cooling fluid, the thermal sensor indicates a reduced temperature on the silicon die proximate the middle channel in FIG. 8.

### Example 40

A device according to FIG. 9 is prepared by providing jet impingement channels above a cold plate. A silicon die, with multiple functionality sections, is in thermal communication with a first surface of the cold plate. A second surface of the cold plate, opposite the first surface, includes the channels. Each jet impingement channel is in fluid communication with an electronic needle valve. A reservoir of R134a as a cooling fluid is provided and fluidically connected to the electronic needle valves. A plurality of outlet channels are also provided above the cold plate. Additionally, a vapor permeable membrane is provided above the cold plate. The outlet channels are fluidically connected to the reservoir of cooling fluid. A pump circulates the fluid from the reservoir to the channels. From the jet impingement channels, the cooling fluid is impinged onto the cold plate and absorbs heat from the silicon die.

A high heat flux associated with the silicon die proximate the middle two jet impingement channels in FIG. 9 is detected by a controller in communication with a thermal sensor. A signal is sent by the controller to the electronic needle valves associated with the middle channel in FIG. 9 to increase a flow rate of the cooling fluid therethrough. After the increased flow of cooling fluid, the thermal sensor indicates a reduced temperature on the silicon die proximate the middle two jet impingement channels in FIG. 9.

### Example 41

Example 40 is repeated with R515B as the cooling fluid.

After the increased flow of cooling fluid, the thermal sensor indicates a reduced temperature on the silicon die proximate the middle two jet impingement channels in FIG. 9.

### Example 42

Example 40 is repeated with R1233zd as the cooling fluid.

After the increased flow of cooling fluid, the thermal sensor indicates a reduced temperature on the silicon die proximate the middle two jet impingement channels in FIG. 9.

### Example 43

Example 40 is repeated with an indium foil thermal interface material provided between the silicon die and the cold plate.

After the increased flow of cooling fluid, the thermal sensor indicates a reduced temperature on the silicon die proximate the middle two jet impingement channels in FIG. 9.

### Example 44

Example 43 is repeated with R515B as the cooling fluid.

After the increased flow of cooling fluid, the thermal sensor indicates a reduced temperature on the silicon die proximate the middle two jet impingement channels in FIG. 9.

### Example 45

Example 43 is repeated with R1233zd as the cooling fluid.

After the increased flow of cooling fluid, the thermal sensor indicates a reduced temperature on the silicon die proximate the middle two jet impingement channels in FIG. 9.

### Example 46

Example 43 is repeated with a porous member provided between the silicon die and the jet impingement channels. The porous section directs the liquid-vapor mixture towards exit channels in the cold plate.

After the increased flow of cooling fluid, the thermal sensor indicates a reduced temperature on the silicon die proximate the middle two jet impingement channels in FIG. 9.

### Example 47

Example 46 is repeated with R515B as the cooling fluid.

After the increased flow of cooling fluid, the thermal sensor indicates a reduced temperature on the silicon die proximate the middle two jet impingement channels in FIG. 9.

### Example 48

Example 46 is repeated with R1233zd as the cooling fluid.

After the increased flow of cooling fluid, the thermal sensor indicates a reduced temperature on the silicon die proximate the middle two jet impingement channels in FIG. 9.

### Example 49

Example 40 is repeated with a porous member provided between the silicon die and the jet impingement channels.

After the increased flow of cooling fluid, the thermal sensor indicates a reduced temperature on the silicon die proximate the middle two jet impingement channels in FIG. 9.

### Example 50

Example 49 is repeated with R515B as the cooling fluid.

After the increased flow of cooling fluid, the thermal sensor indicates a reduced temperature on the silicon die proximate the middle two jet impingement channels in FIG. 9.

### Example 51

Example 49 is repeated with R1233zd as the cooling fluid.

After the increased flow of cooling fluid, the thermal sensor indicates a reduced temperature on the silicon die proximate the middle two jet impingement channels in FIG. 9.

### Example 52

Example 1 is repeated with PG25 as the cooling fluid.

After the increased flow of cooling fluid, the thermal sensor indicates a reduced temperature on the silicon die opposite the left-most channel in FIG. 2.

### Example 53

Example 4 is repeated with PG25 as the cooling fluid.

After a high temperature is sensed in the fluid channel, a signal is sent to the controller to open the valve and increase coolant flow rate in this channel. After the increased flow of cooling fluid, the thermal sensor indicates a reduced temperature at section 14b of the silicon die in FIG. 3.

### Example 54

Example 7 is repeated with PG25 as the cooling fluid.

After the increased flow of cooling fluid, the thermal sensor indicates a reduced temperature on the upper silicon die proximate the right most-channel in FIG. 4.

### Example 55

Example 16 is repeated with PG25 as the cooling fluid.

After the increased flow of cooling fluid, the thermal sensor indicates a reduced temperature on the silicon die opposite the fourth from the left side channel in FIG. 6.

### Example 56

Example 25 is repeated with PG25 as the cooling fluid.

After the increased flow of cooling fluid, the thermal sensor indicates a reduced temperature on the silicon die opposite the fourth from the left side channel in FIG. 6.

### Example 57

Example 1 is repeated but applied to data center servers and computing equipment.

After the increased flow of cooling fluid, the thermal sensor indicates a reduced temperature on the data center server/computing equipment opposite the left-most channel in FIG. 2.

### Example 58

A high-performance computing system can process data and perform complex calculations at high speeds. An example of a high-performance computing system is a supercomputer. This high-performance computing equipment use powerful processors which generate a significant amount of heat, and without effective cooling, these components can overheat, leading to performance degradation, system instability, and even hardware failure. Proper cooling ensures optimal performance and reliability by maintaining stable operating temperatures

Example 1 is repeated but applied to high-performance computing equipment.

After the increased flow of cooling fluid, the thermal sensor indicates a reduced temperature on the high-performance computing equipment opposite the left-most channel in FIG. 2.

### Example 59

A cryptocurrency mining rig is a custom-build PC designed specifically for the process of mining cryptocurrencies like Bitcoin, where it uses powerful graphics processing units (GPUs) to solve complex mathematical equations and verify transactions on the blockchain, earning rewards in the form of cryptocurrency for its efforts. These cryptocurrency mining rigs generate a significant amount of heat due to the intensive computational processes involved. Efficient cooling systems are essential to maintain optimal operating conditions for mining hardware. Improper or insufficient cooling can lead to overheating which in turn causes an increased electricity consumption, lower computational efficiency, and reduced lifespan of the mining rig.

Example 1 is repeated but applied to cryptocurrency mining rig.

After the increased flow of cooling fluid, the thermal sensor indicates a reduced temperature on the cryptocurrency mining rig opposite the left-most channel in FIG. 2.

### Example 60

Electric vehicles use electric motors to power the vehicle instead of an internal combustion engine. Common types of electric motors used in electric vehicles include brushless DC motors and permanent magnet synchronous motors. The electric vehicle controller is the electronics package that operates between the batteries and the motor to control the electric vehicle speed and acceleration. Both the electric motors, electronic motor controllers as well as the battery packs used to power the various equipment generate heat during their operation and efficient cooling system is important for their operation.

Example 1 is repeated but applied to a component of an electric motor.

After the increased flow of cooling fluid, the thermal sensor indicates a reduced temperature on the component of an electric motor opposite the left-most channel in FIG. 2.

### Example 61

Light commercial vehicles are typically used for everyday commercial tasks. Examples include small delivery vans, pickup trucks, and cargo vans. They are ideal for light hauling and urban deliveries. Medium duty trucks are designed for more demanding commercial applications. This category includes larger box trucks, utility trucks, and delivery trucks. They offer greater payload capacity and are accordingly used for more substantial deliveries and vocational purposes. Heavy duty trucks are essential for long-haul transport and handling extremely heavy loads, making them crucial for industries requiring substantial hauling capacity. They include tractor-trailers, dump trucks, and large refuse trucks. All these commercial vehicles can either be powered by an internal combustion engine or electric motors. Additionally, they might also have battery packs to power several electronics and electrical motors. In either case, the electric motors and the battery packs used to power these motors in electric vehicles and the electronics used in internal combustion vehicles generate heat during their operation and proper thermal management is needed for efficient and safe functioning. An electric aircraft is an aircraft powered by electricity. Electric aircraft reduce the environmental effects of aviation, providing zero emissions and quieter flights. Electricity may be supplied by a variety of methods, such as batteries, ultracapacitors and fuel cells. Additionally, the electric aircraft have electric motors which drive propellers or turbines. These batteries, ultracapacitors, fuel cells and electric motors generate heat and thus require proper thermal management.

After the increased flow of cooling fluid, the thermal sensor indicates a reduced temperature on the silicon die opposite the fourth from the left side channel in FIG. 6.

Example 1 is repeated but applied to a component of vehicle.

After the increased flow of cooling fluid, the thermal sensor indicates a reduced temperature on the component of vehicle opposite the left-most channel in FIG. 2.

### SPECIFIC EMBODIMENTS

While the following is described in conjunction with specific embodiments, it will be understood that this description is intended to illustrate and not limit the scope of the preceding description and the appended claims.

A first embodiment of the invention is a device comprising a source of a cooling fluid; a first plurality of cooling channels in fluid communication with the source of the cooling fluid and configured to receive a first portion of the cooling fluid which receives heat transferred from a first section of a chip having a first functionality; and, a second plurality of cooling channels in fluid communication with the source of the cooling fluid and configured to receive a second portion of the cooling fluid which receives heat transferred from a second section of the chip having a second functionality, the second functionality being the same as or different from the first functionality, wherein a flow rate of the first portion of the cooling fluid in the first plurality of cooling channels is configured to be controlled independently from a flow rate of the second portion of the cooling fluid in the second plurality of cooling channels, and wherein the cooling fluid comprises a two-phase cooling fluid. An embodiment of the invention is one, any or all of prior embodiments in this paragraph up through the first embodiment in this paragraph, wherein the first plurality of cooling channels are formed integrally with the first section of the chip, or wherein the second plurality of cooling channels are formed integrally with the second section of the chip, or both. An embodiment of the invention is one, any or all of prior embodiments in this paragraph up through the first embodiment in this paragraph, wherein a flow rate through each channel is configured to be individually controlled. An embodiment of the invention is one, any or all of prior embodiments in this paragraph up through the first embodiment in this paragraph, wherein a flow rate though at least two channels from the first plurality of cooling channels are configured to be controlled together, or wherein a flow rate though at least two channels from the second plurality of cooling channels are configured to be controlled together, or both. An embodiment of the invention is one, any or all of prior embodiments in this paragraph up through the first embodiment in this paragraph, wherein the first plurality of cooling channels are further configured to receive the first portion of the cooling fluid which further receives heat transferred from a first section of a second chip, the second chip different from the chip. An embodiment of the invention is one, any or all of prior embodiments in this paragraph up through the first embodiment in this paragraph, wherein the first plurality of cooling channels comprise jet impingement channels, or wherein the second plurality of cooling channels comprise jet impingement channels, or both. An embodiment of the invention is one, any or all of prior embodiments in this paragraph up through the first embodiment in this paragraph, further comprising a porous member between the channels and the chip. An embodiment of the invention is one, any or all of prior embodiments in this paragraph up through the first embodiment in this paragraph, wherein the first plurality of cooling channels are formed integrally with a first cold plate in thermal communication with the first section of the chip, or wherein the second plurality of cooling channels are formed integrally with a second cold plate in thermal communication with the second section of the chip, or both. An embodiment of the invention is one, any or all of prior embodiments in this paragraph up through the first embodiment in this paragraph, further comprising a thermal interface material or porous structure between the first cold plate and the first second of the chip, or between the second cold plate and the second section of the chip, or both. An embodiment of the invention is one, any or all of prior embodiments in this paragraph up through the first embodiment in this paragraph, further comprising wherein the first plurality of cooling channels comprise jet impingement channels, or wherein the second plurality of cooling channels comprise jet impingement channels, or both. An embodiment of the invention is one, any or all of prior embodiments in this paragraph up through the first embodiment in this paragraph, further comprising a porous member between the jet impingement channels and the chip. An embodiment of the invention is one, any or all of prior embodiments in this paragraph up through the first embodiment in this paragraph, further comprising a vapor permeable membrane between the jet impingement channels and the porous member. An embodiment of the invention is one, any or all of prior embodiments in this paragraph up through the first embodiment in this paragraph, wherein the cooling channels from the first plurality of flow channels are parallel with each other, or the cooling channels from the second plurality of flow channels are parallel with each other, or both. An embodiment of the invention is one, any or all of prior embodiments in this paragraph up through the first embodiment in this paragraph, further comprising a flow control device configured to adjust the flow rate of at least one channel from the first plurality of channels.

A second embodiment of the invention is a process for controlling a temperature of an electronic chip, the process comprising passing a first portion of the cooling fluid through a first plurality of cooling channels; transferring heat from a first section of a chip having a first functionality to the first portion of the cooling fluid in the first plurality of cooling channels; passing a second portion of the cooling fluid through a second plurality of cooling channels; transferring heat from a second section of the chip, having a second functionality independent of the first functionality, to the second portion of the cooling fluid in the second plurality of cooling channels; and, wherein a flow rate of the first portion of the cooling fluid in the first plurality of cooling channels is configured to be adjusted independently from a flow rate of the second portion of the cooling fluid in the second plurality of cooling channels, wherein the cooling fluid comprises a two-phase cooling fluid. An embodiment of the invention is one, any or all of prior embodiments in this paragraph up through the second embodiment in this paragraph, further comprising monitoring a temperature of the first section of the chip; and, adjusting, based on the temperature of the first section of the chip, the flow rate of the first portion of the cooling fluid through the first plurality of cooling channels. An embodiment of the invention is one, any or all of prior embodiments in this paragraph up through the second embodiment in this paragraph, further comprising monitoring a temperature of the second section of the chip; and, adjusting, based on the temperature of the second section of the chip, the flow rate of the second portion of the cooling fluid through the second plurality of cooling channels. An embodiment of the invention is one, any or all of prior embodiments in this paragraph up through the second embodiment in this paragraph, further comprising monitoring an electrical power consumption, a heat flux map, or both of the first section of the chip; and, adjusting, based on the electrical power consumption, the heat flux map, or both of the first section of the chip, the flow rate of the first portion of the cooling fluid through the first plurality of cooling channels. An embodiment of the invention is one, any or all of prior embodiments in this paragraph up through the second embodiment in this paragraph, further comprising monitoring an electrical power consumption, a heat flux map, or both of the second section of the chip; and, adjusting, based on the electrical power consumption, the heat flux map, or both of the second section of the chip, the flow rate of the second portion of the cooling fluid through the second plurality of cooling channels. An embodiment of the invention is one, any or all of prior embodiments in this paragraph up through the second embodiment in this paragraph, further comprising adjusting the flow rate of the first portion of the cooling fluid in the first plurality of cooling channels with a flow control device. An embodiment of the invention is one, any or all of prior embodiments in this paragraph up through the second embodiment in this paragraph, further comprising adjusting the flow rate of the second portion of the cooling fluid in the second plurality of cooling channels with a flow control device. An embodiment of the invention is one, any or all of prior embodiments in this paragraph up through the second embodiment in this paragraph, further comprising monitoring a pressure associated with the two-phase cooling fluid; and, adjusting, based on the pressure the flow rate of the first portion of the cooling fluid through the first plurality of cooling channels, or adjusting, based on the pressure, the flow rate of the second portion of the cooling fluid through the second plurality of cooling channels, or adjusting, based on the pressure, both. An embodiment of the invention is one, any or all of prior embodiments in this paragraph up through the second embodiment in this paragraph, wherein the pressure comprises a liquid pressure, a vapor pressure, or a liquid-vapor mixture pressure.

A third embodiment of the invention is a device comprising: a source of a cooling fluid; a first cooling channel in fluid communication with the source of the cooling fluid and configured to receive a first portion of the cooling fluid which receives heat transferred from a first section of an electronic component having a first functionality; and, a second cooling channel in fluid communication with the source of the cooling fluid and configured to receive a second portion of the cooling fluid which receives heat transferred from a second section of the electronic component having a second functionality, the second functionality being the same as or different from the first functionality, wherein a flow rate of the first portion of the cooling fluid in the first cooling channel is configured to be controlled independently from a flow rate of the second portion of the cooling fluid in the second cooling channel.

Without further elaboration, it is believed that using the preceding description that one skilled in the art can utilize the present invention to its fullest extent and easily ascertain the essential characteristics of this invention, without departing from the spirit and scope thereof, to make various changes and modifications of the invention and to adapt it to various usages and conditions. The preceding preferred specific embodiments are, therefore, to be construed as merely illustrative, and not limiting the remainder of the disclosure in any way whatsoever, and that it is intended to cover various modifications and equivalent arrangements included within the scope of the appended claims.

In the foregoing, all temperatures are set forth in degrees Celsius and, all parts and percentages are by weight, unless otherwise indicated.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A device comprising:
a source of a cooling fluid;
a first cooling channel in fluid communication with the source of the cooling fluid and configured to receive a first portion of the cooling fluid which receives heat transferred from a first section of an electronic component having a first functionality; and,
a second cooling channel in fluid communication with the source of the cooling fluid and configured to receive a second portion of the cooling fluid which receives heat transferred from a second section of the electronic component having a second functionality, the second functionality being the same as or different from the first functionality,
wherein a flow rate of the first portion of the cooling fluid in the first cooling channel is configured to be controlled independently from a flow rate of the second portion of the cooling fluid in the second cooling channel.

2. A device comprising:
a source of a cooling fluid;
a first plurality of cooling channels in fluid communication with the source of the cooling fluid and configured to receive a first portion of the cooling fluid which receives heat transferred from a first section of a chip having a first functionality; and,
a second plurality of cooling channels in fluid communication with the source of the cooling fluid and configured to receive a second portion of the cooling fluid which receives heat transferred from a second section of the chip having a second functionality, the second functionality being the same as or different from the first functionality,
wherein a flow rate of the first portion of the cooling fluid in the first plurality of cooling channels is configured to be controlled independently from a flow rate of the second portion of the cooling fluid in the second plurality of cooling channels, and
wherein the cooling fluid comprises a single phase cooling fluid or a two-phase cooling fluid.

3. The device of claim 2, wherein the first plurality of cooling channels are formed integrally with the first section of the chip, or wherein the second plurality of cooling channels are formed integrally with the second section of the chip, or both.

4. The device of claim 2, wherein a flow rate though at least two channels from the first plurality of cooling channels are configured to be controlled together, or wherein a flow rate though at least two channels from the second plurality of cooling channels are configured to be controlled together, or both.

5. The device of claim 2, wherein the first plurality of cooling channels are further configured to receive the first portion of the cooling fluid which further receives heat transferred from a first section of a second chip, the second chip different from the chip.

6. The device of claim 2, wherein the first plurality of cooling channels comprise jet impingement channels, or wherein the second plurality of cooling channels comprise jet impingement channels, or both.

7. The device of claim 2, wherein the cooling fluid comprises the two-phase cooling fluid and the device further comprising a porous element between the first and second pluralities of cooling channels and the chip.

8. The device of claim 2, wherein the first plurality of cooling channels are formed integrally with a first cold plate in thermal communication with the first section of the chip, or wherein the second plurality of cooling channels are formed integrally with a second cold plate in thermal communication with the second section of the chip, or both.

9. The device of claim 8, further comprising:
a thermal interface material or a porous structure between the first cold plate and the first section of the chip, or between the second cold plate and the second section of the chip, or both.

10. The device of claim 8, further comprising:
wherein the first plurality of cooling channels comprise jet impingement channels, or wherein the second plurality of cooling channels comprise jet impingement channels, or both.

11. The device of claim 10, further comprising a porous element between the jet impingement channels and the chip, and optionally further comprising a vapor permeable membrane between the jet impingement channels and the porous element.

12. The device of claim 2, further comprising:
a flow control device configured to adjust the flow rate of at least one channel from the first plurality of channels.

13. A process for controlling temperature of an electronic chip, the process comprising:
passing a first portion of a cooling fluid through a first plurality of cooling channels;
transferring heat from a first section of a chip having a first functionality to the first portion of the cooling fluid in the first plurality of cooling channels;
passing a second portion of the cooling fluid through a second plurality of cooling channels;
transferring heat from a second section of the chip, having a second functionality independent of the first functionality, to the second portion of the cooling fluid in the second plurality of cooling channels; and,
wherein a flow rate of the first portion of the cooling fluid in the first plurality of cooling channels is configured to be adjusted independently from a flow rate of the second portion of the cooling fluid in the second plurality of cooling channels,
wherein the cooling fluid comprises a two-phase cooling fluid.

14. The process of claim 13, further comprising:
monitoring a temperature of the first section of the chip; and,
adjusting, based on the temperature of the first section of the chip, the flow rate of the first portion of the cooling fluid through the first plurality of cooling channels, and, optionally monitoring a temperature of the second section of the chip, and,
adjusting, based on the temperature of the second section of the chip, the flow rate of the second portion of the cooling fluid through the second plurality of cooling channels.

15. The process of claim 13, further comprising:
monitoring an electrical power consumption, a heat flux map, or both of the first section of the chip; and,
adjusting, based on the electrical power consumption, the heat flux map, or both of the first section of the chip, the flow rate of the first portion of the cooling fluid through the first plurality of cooling channels.

16. The process of claim 15, further comprising:
monitoring an electrical power consumption, a heat flux map, or both of the second section of the chip; and,
adjusting, based on the electrical power consumption, the heat flux map, or both of the second section of the chip, the flow rate of the second portion of the cooling fluid through the second plurality of cooling channels.

17. The process of claim 13, further comprising:
adjusting the flow rate of the first portion of the cooling fluid in the first plurality of cooling channels with a flow control device.

18. The process of claim 13, further comprising:
adjusting the flow rate of the second portion of the cooling fluid in the second plurality of cooling channels with a flow control device.

19. The process of claim 13, further comprising:
monitoring a pressure associated with the two-phase cooling fluid; and,
adjusting, based on the pressure the flow rate of the first portion of the cooling fluid through the first plurality of cooling channels, or adjusting, based on the pressure, the flow rate of the second portion of the cooling fluid through the second plurality of cooling channels, or adjusting, based on the pressure, both.

20. The process of claim 19, wherein the pressure comprises a liquid pressure, a vapor pressure, or a liquid-vapor mixture pressure.
